(19) United States
(12) Patent Application Publication
(10) Pub. No.: US 2012/0162181 A1
(43) Pub. Date: Jun. 28, 2012

(54) DISPLAY PANEL, PIXEL CIRCUIT AND DRIVING METHOD OF DIFFERENTIAL VOLTAGE DRIVEN DEVICE THEREIN

(75) Inventors: Young-Ran CHUANG, Hsin-Chu (TW); Wen-Bin Lo, Hsin-Chu (TW); Wei-Jhih Lian, Hsin-Chu (TW); Cheng-Yeh Tsai, Hsin-Chu (TW); Tai-Hsiang Huang, Hsin-Chu (TW); Po-Lun Chen, Hsin-Chu (TW)

(73) Assignee: AU OPTRONICS CORP., HSINCHU (TW)

(21) Appl. No.: 13/191,881

(22) Filed: Jul. 27, 2011

(30) Foreign Application Priority Data
Dec. 23, 2010 (TW) 099145594

(51) Int. Cl. G06F 3/038; H01L 29/786; H01L 33/16

(52) U.S. Cl. 345/212; 257/59; 257/71; 257/57; 257/E33.003; 257/E33.004; 257/E29.273

(57) ABSTRACT

A display panel, a pixel circuit and a driving method of a differential voltage driving device are disclosed. The driving method includes: respectively supplying an alternating common voltage in a first polarity and a first display data in a second polarity to two terminals of the differential voltage driven device in a first frame; disconnecting the differential voltage driven device from the alternating common voltage, thereby keeping one terminal of the differential voltage driving device at the first polarity of the alternating common voltage; converting the alternating common voltage to the second polarity in a second frame which is consecutive to the first frame; and respectively supplying the alternating common voltage in the second polarity and a second display data in the first polarity to the two terminals of the differential voltage driving device in the second frame, here the first polarity is inverse to the second polarity.

### TECHNICAL FIELD

The disclosure relates to a display panel and a driving method of the same, and more particularly to a display panel and a driving method of the same utilizing a common voltage and a polarity-inverse display data for displaying a same frame.

### BACKGROUND

FIG. 1 is a schematic circuit diagram of a dot-inversion display panel. As depicted in FIG. 1, the dot-inversion display panel 10 comprises multiple pixel circuits (for a better explanation, the exemplary dot-inversion display panel 10 consists 5*5 pixel circuits). Each of the pixel circuits and its four neighboring pixel circuits are respectively electrically coupled to data lines supplying display data in different polarities. For example, as depicted in FIG. 1, if the display data, supplied to the pixel circuit (3,3) and used for displaying a specific frame, is a positive-polarity display data Data+, accordingly the display data, supplied to the four neighboring pixel circuits (2,3), (3,2), (3,4), (4,3) of the pixel circuit (3,3) and used for displaying the same specific frame, respectively are negative-polarity display data Data−. Furthermore, any two consecutive display data, sequentially supplied to a same pixel circuit and respectively used for displaying two consecutive frames, are polarity-inverse to each other. For example, as depicted in FIG. 1, if the display data supplied to the pixel circuit (3,3) and used for displaying a frame is in a positive polarity, the next display data supplied to the pixel circuit (3,3) and used for displaying a next frame is accordingly in a negative polarity. Moreover, each of the pixel circuits is electrically coupled to a common voltage line Vcom, as depicted in FIG. 1.

In the dot-inversion display panel 10, the ON/OFF of a pixel circuit is controlled by a gate line voltage on a scan line which the pixel circuit is electrically coupled to, and the brightness degree generated by a pixel circuit is controlled by a crossing voltage, which is indicated that a differential voltage resulted by a voltage of the display data and a voltage on the common voltage line Vcom supplied to the pixel circuit. For example, as depicted in FIG. 1, the ON/OFF of the pixel circuit (3,3) is controlled by the gate line voltage on the scan line Scan-3, and the brightness degree generated by the pixel circuit (3,3) is controlled by the crossing voltage between the voltage on the positive-polarity display data Data+ and the voltage on the common voltage line Vcom which both are supplied to the pixel circuit (3,3).

FIG. 2 is a schematic circuit diagram of a pixel circuit of the dot-inversion display panel 10. As depicted in FIG. 2, the pixel circuit 20 comprises a first transistor T1 and a capacitor C1. The control terminal of the first transistor T1 is electrically coupled to its corresponding scan line Scan; the first terminal of the first transistor T1 is electrically coupled to its corresponding data line; the second terminal of the first transistor T1 is electrically coupled to one terminal of the capacitor C1; the other terminal of the capacitor C1 is electrically coupled to the common voltage Vcom. As described above, when the first transistor T1 is conductive by the gate line voltage on the scan line Scan, consequently the display data on the data line Data is supplied to one terminal of the capacitor C1 via the conductive first transistor T1, thereby the pixel circuit 20 can generate a corresponding brightness degree according to the crossing voltage, which is resulted by the voltage of the display data at the one terminal of the capacitor C1 and the voltage on the common voltage line Vcom. As depicted in FIG. 2, the crossing voltage of the pixel circuit 20 can be also referred to the crossing voltage of the two terminals of the capacitor C1.

In the dot-inversion display panel 10, because the voltage on the common voltage line Vcom has a fixed value, thereby the crossing voltage of the two terminals of the capacitor C1 may be not large enough to successfully drive a pixel circuit adopted in some display panels of specific types which require a relatively high crossing voltage. For example, as depicted in FIG. 2, if the common voltage line Vcom supplies a fixed-value voltage (e.g., 8V), and at the same time the data line Data supplies a display data (e.g., 0V) with a negative polarity compared to the voltage on the common voltage line Vcom to the pixel circuit 20, the maximum crossing voltage of the two terminals of the capacitor C1 is about 8V. Similarly, if the common voltage line Vcom supplies a fixed-value voltage (e.g., 8V), and at the same time the data line Data supplies a display data (e.g., 16V) with a positive polarity compared to the voltage on the common voltage line Vcom to the pixel circuit 20, the maximum crossing voltage of the two terminals of the capacitor C1 is also about 8V. The maximum crossing voltage (e.g., about 8V) is not large enough to successfully drive some display panels of specific types (such as a blue polarity display panel which requires a crossing voltage of at least 10V); thereby the pixel circuit 20 cannot generate the brightness degree effectively.

### SUMMARY OF THE INVENTION

Therefore, the present invention is directed to provide a display panel and a driving method of the same capable of increasing a crossing voltage of a pixel circuit in the display panel.

The present invention provides a driving method of a differential voltage driven device comprising steps of: supplying an alternating common voltage in a first polarity to a first terminal of the differential voltage driven device and supplying a first display data in a second polarity to a second terminal of the differential voltage driven device in a first frame; disconnecting the differential voltage driven device from the alternating common voltage, thereby keeping the first terminal at the first polarity of the alternating common voltage; converting the alternating common voltage to the second polarity in a second frame which is consecutive to the first frame; and supplying the alternating common voltage in the second polarity to the first terminal of the differential voltage driven device and supplying a second display data in the first polarity to the second terminal of the differential voltage driven device in the second frame, wherein the first polarity is inverse to the second polarity, and the differential voltage driven device performs a corresponding operation according to a differential voltage between the first and second terminals thereof.

The present invention further provides a display panel comprising: a plurality of data lines; a plurality of scan lines; two groups of common voltage lines for respectively supplying different voltages with polarity-inverse to each other; and a plurality of pixel circuits, arranged in array, wherein each of the pixel circuits is electrically coupled to one of the data lines and one of the scan lines, and each of the pixel circuits comprises: a first switch, electrically coupled to the corresponding scan line and the corresponding data line and for determining whether to transmit a voltage on the corresponding data line according to a gate line voltage on the corresponding scan line; a second switch, electrically coupled to one of the two groups of common voltage lines and the corresponding scan line for determining whether to transmit a voltage on the coupled common voltage lines according to a gate line voltage on the corresponding scan line; and a capacitor, wherein one terminal of the capacitor is electrically coupled to the first switch for receiving the voltage on the corresponding data line, and the other terminal of the capacitor is electrically coupled to the second switch for receiving the voltage on the coupled common voltage lines, wherein the two voltages respectively received by the two terminals of the capacitor in each of the pixel circuits are polarity-inverse to each other.

In accordance with an embodiment of the present invention, the above mentioned first and second switches are thin film transistors.

In accordance with an embodiment of the present invention, the above mentioned two groups of common voltage lines generally extend in a same direction of the data lines.

In accordance with another embodiment of the present invention, the above mentioned two groups of common voltage lines generally extend in a same direction of the scan lines.

In accordance with an embodiment of the present invention, any two of the pixel circuits, consecutively electrically coupled to a same one of the data lines, are respectively arranged on two sides of the data line, and are electrically coupled to a same one of the two groups of common voltage lines.

In accordance with an embodiment of the present invention, the pixel circuits of a same column are alternately electrically couple to the two groups of common voltage lines, the pixel circuits of a same row are alternately electrically couple to two groups of common voltage lines.

In accordance with another embodiment of the present invention, the above mentioned thin film transistor comprises: a first mental layer; an isolation layer, formed on top of the first mental layer; a second mental layer, formed on top of the isolation layer; and an indium tin oxide, form on top of the second mental layer, wherein a full contact is formed between the second mental layer and the indium tin oxide

The present invention still further provides a pixel circuit electrically which is coupled to a data line, a scan line and a common voltage line. The pixel circuit comprises: a first switch, electrically coupled to the scan line and the data line for determining whether to transmit a voltage on the data line according to a gate line voltage on the scan line; a second switch, electrically coupled to the common voltage line and the scan line for determining whether to transmit a voltage on the common voltage line according to the gate line voltage on the scan line; and a capacitor, wherein one terminal of the capacitor is electrically coupled to the first switch for receiving a voltage on the data line, and the other terminal of the capacitor is electrically coupled to the second switch for receiving a voltage on the common voltage line, wherein the two voltages respectively received by the two terminals of the capacitor are polarity-inverse to each other.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic circuit block diagram of a conventional dot-inversion display panel;

FIG. 2 is a schematic circuit diagram of a pixel circuit configured in the dot-inversion display panel;

FIG. 3 is a schematic circuit block diagram of a dot-inversion display panel in accordance with an embodiment of the present invention;

FIG. 4A is a schematic circuit diagram of a pixel circuit configured in the dot-inversion display panel in accordance with an embodiment of the present invention;

FIG. 4B is a schematic diagram illustrating a cross-sectional view of a manufacture procedure of a thin film transistor in accordance with an embodiment of the present invention;

FIG. 4C is a schematic diagram illustrating a cross-sectional view of a manufacture procedure of a thin film transistor in accordance with another embodiment of the present invention; and

FIG. 5 is a schematic circuit block diagram of a dot-inversion display panel in accordance with another embodiment of the present invention.

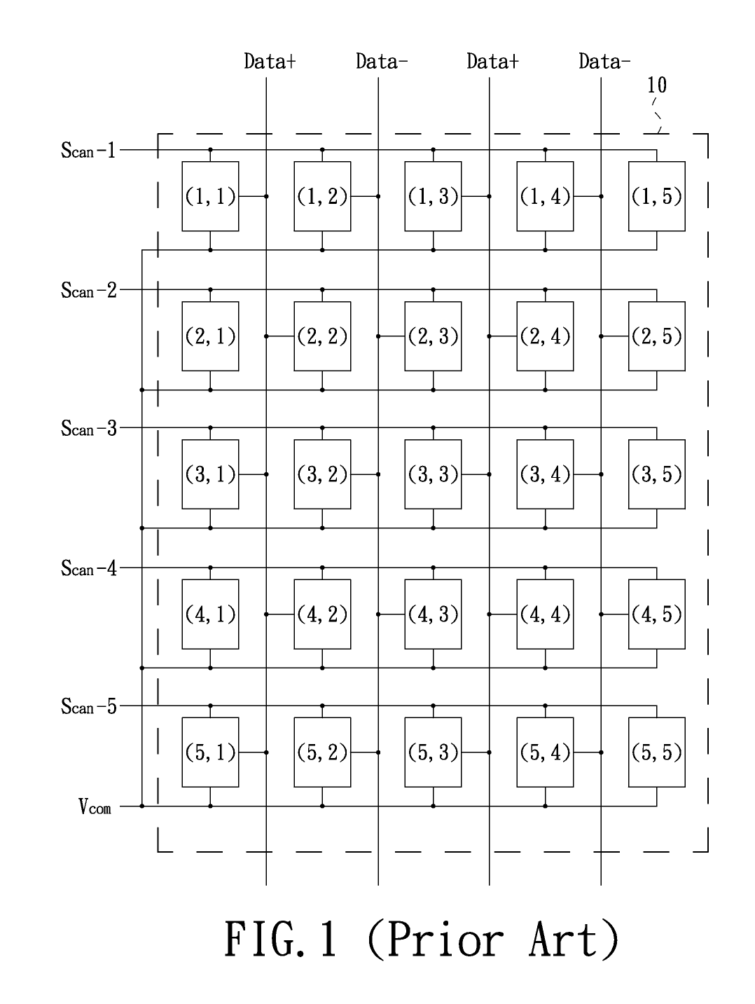

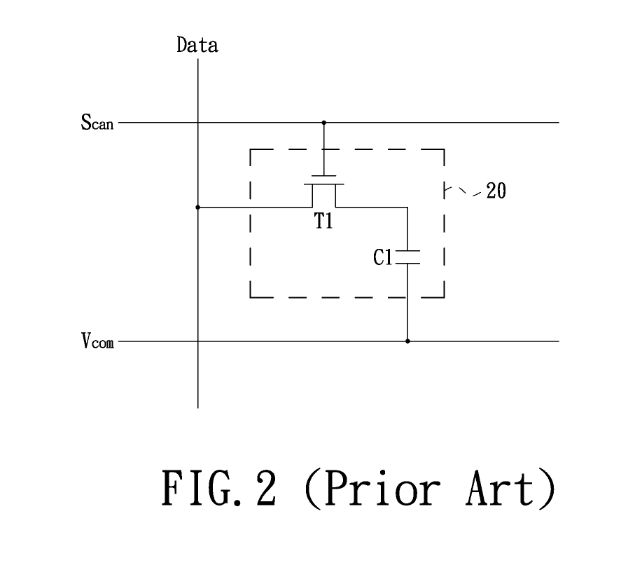

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

When a normal display panel displays a same gray level in multiple consecutive frames, the voltage of display data supplied to a same pixel circuit is changed between a relatively high value and a relatively low value. Similarly, in the present invention, the common voltage supplied to a same pixel is also changed between a relatively high value and a relatively low value. In specific, if the display data or the common voltage having a relatively high voltage value, the display data or the common voltage is defined in the first polarity; alternatively, if the display data or the common voltage having a relatively low voltage value, the display data or the common voltage is defined in the second polarity, wherein the first and second polarities have a 180° difference. Therefore, when a display data and a common voltage are supplied to a same pixel circuit for displaying a same frame, the display data is accordingly in the first polarity if the common voltage is in the second polarity; alternatively, the display data is accordingly in the second polarity if the common voltage is in the first polarity.

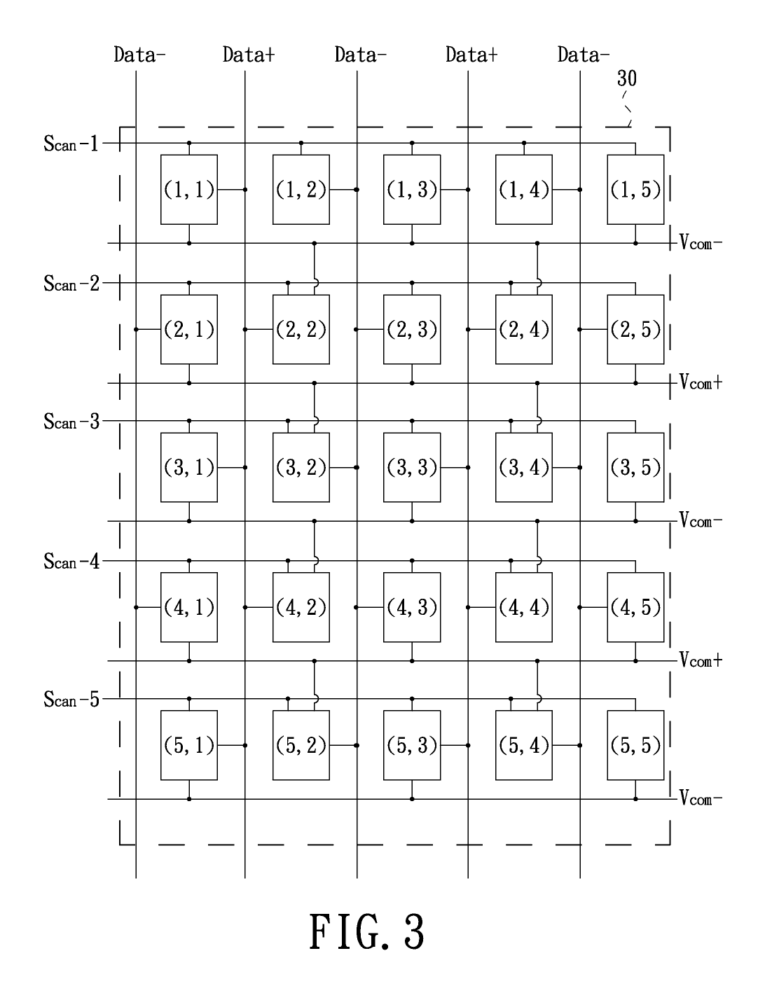

FIG. 3 is a schematic circuit block diagram of a dot-inversion display panel 30 in accordance with an embodiment of the present invention. As depicted in FIG. 3, the dot-inversion display panel 30 comprises multiple pixel circuits. For a better explanation of the embodiment, the exemplary dot-inversion display panel 30 consists of 5*5 pixel circuits. As described above, the multiple pixel circuits of a same row are electrically coupled to a same scan line. For example, as depicted in FIG. 3, the five pixel circuits (1,1), (1,2), . . . , (1,5) of the first row are electrically coupled to the scan line Scan-1. In addition, the multiple pixel circuits of a same column are alternately electrically coupled to a data line with a first-polarity display data Data+ and a data line with a second-polarity display data Data−. For example, as depicted in FIG. 3, the three odd pixel circuits (1,2), (3,2), (5,2) of the second column are electrically coupled to a data line for supplying the second-polarity display data Data−; and the two even pixel circuits (2,2), (4,2) of the second column are electrically coupled to a data line for supplying the first-polarity display data Data+. Similarly, the multiple pixel circuits of a same row are also alternately electrically coupled to the data lines with a first-polarity display data Data+ and the data lines with a second-polarity display data Data−. For example, as depicted in FIG. 3, the three consecutive odd pixel circuits (2,1), (2,3), (2,5) of the second row are respectively electrically coupled to three data lines for supplying the second-polarity display data Data−, and the two even pixel circuits (2,2), (2,4) of the second row are respectively electrically coupled to two data lines for supplying the first-polarity display data Data+.

As depicted in FIG. 3, the dot-inversion display panel 30 further comprises two groups of common voltage lines from which either a first-polarity common voltage Vcom+ or a second-polarity common voltage Vcom− is supplied alternately. That is, if one group of common voltage lines is configured to supply the first-polarity common voltage Vcom+, at the same time the other group of common voltage lines is accordingly configured to supply the second-polarity common voltage Vcom−. In addition, each of the pixel circuits is electrically coupled to either one of the two groups of common voltage lines, and the common voltage supplied to a pixel circuit is polarity-inverse to the display data supplied to the same pixel circuit; and therefore, the multiple pixel circuits of each column (or each row) are alternately electrically coupled to the first-polarity common voltage Vcom+ and the second-polarity common voltage Vcom− under a dot-inversion condition. For example, as depicted in FIG. 3, if the data line electrically coupled to the pixel circuit (3,3) is configured to supply the first-polarity display data Data+ at a specific period, the common voltage line electrically coupled to the pixel circuit (3,3) is accordingly configured to supply the second-polarity common voltage Vcom− in the same specific period; and therefore, the data lines and common voltage lines electrically coupled to the four neighboring pixel circuits (3,2), (3,4), (2,3), (4,3) of the pixel circuit (3,3) are respectively configured to supply the second-polarity display data Data− and the first-polarity common voltage Vcom+ in the same specific period.

Moreover, to each of the pixel circuits, display data respectively for displaying any two consecutive frames are polarity-inverse to each other; thereby the two consecutive common voltages respectively for displaying two consecutive frames are needed to be polarity-inverse to each other. For example, as depicted in FIG. 3, if the pixel circuit (3,3) is configured to display a frame and the data line, electrically coupled to the pixel circuit (3,3), is configured to supply the first-polarity display data Data+ for the frame, and accordingly the common voltage line, electrically coupled to the pixel circuit (3,3), is configured to supply the second-polarity common voltage Vcom− for the same frame. Consequently, when the pixel circuit (3,3) is configured to display a next frame, the same data line is converted to supply the second-polarity display data Data− for the next frame, and accordingly the same scan line is converted to supply the first-polarity common voltage Vcom+ for the next frame. Therefore, in the dot-inversion display panel 30 of the present invention, because the data line and the common voltage line, electrically coupled to a same pixel circuit and for supplying data for displaying a same frame, are polarity-inverse to each other, thereby the pixel circuit can obtain a higher crossing voltage than conventional technology, and therefore the higher crossing voltage is able to drive a display panel of specific type, such as the blue-polarity display panel requiring a higher crossing voltage, to generate a proper brightness degree.

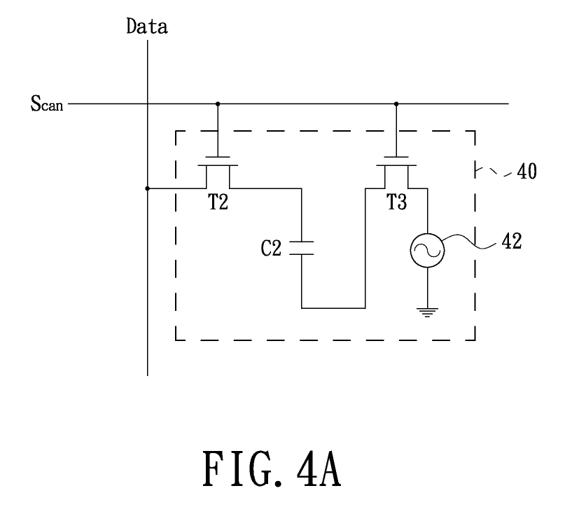

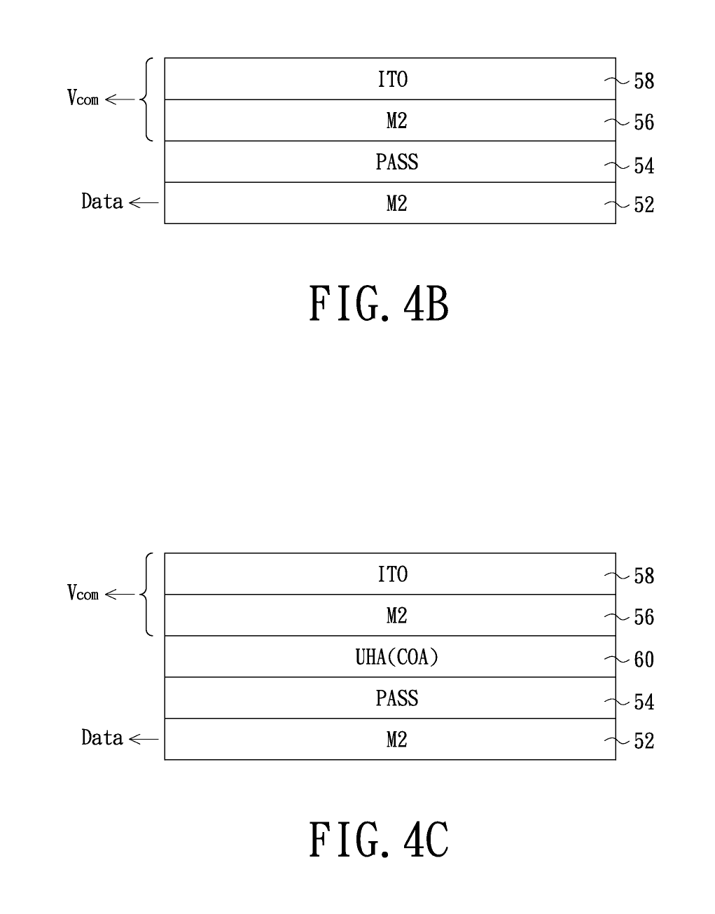

Please refer to FIG. 4A which is a schematic circuit diagram of each of the pixel circuits configured in the dot-inversion display panel 30 in accordance with an embodiment of the present invention. As depicted in FIG. 4A, the pixel circuit 40 comprises a second transistor T2, a third transistor T3 and a capacitor C2. The control terminal of the second transistor T2 is electrically coupled to its corresponding scan line Scan; the first terminal of the second transistor T2 is electrically coupled to its corresponding data line Data and for receiving a display data; the second terminal of the second transistor T2 is electrically coupled to one terminal of the capacitor C2; the control terminal of the third transistor T3 is electrically coupled to the same scan line Scan; the first terminal of the third transistor T3 is electrically coupled to the other terminal of the capacitor C2; the second terminal of the third transistor T3 is electrically coupled to an alternating voltage source 42, which is used for alternately supplying the first-polarity common voltage Vcom+ and the second-polarity common voltage Vcom−.

In particular, not every single pixel circuit 40 is needed to be implemented with an alternating voltage source 42. In other words, multiple pixel circuits 40 can share a same alternating voltage source 42 at a same time according to a corresponding design.

As described above, because the display data supplied from the data line Data is polarity-inverse to the common voltage supplied from the alternating voltage source 42 when the pixel circuit 40 is configured to display a same frame; therefore, the two voltages respectively at the two terminals of the capacitor C2 are accordingly polarity-inverse to each other when the pixel circuit 40 is configured to display the same frame. For example, if the data line Data supplies a first-polarity display data Data+ to the pixel circuit 40 for displaying a specific frame, accordingly the alternating voltage source 42 is configured to supply the second-polarity common voltage Vcom− to the pixel circuit 40 for displaying the same frame. When the first-polarity display data Data+(e.g., 16V) is further transmitted to one terminal of the capacitor C2 via the conductive second transistor T2 and the second-polarity common voltage Vcom− (e.g., 0V) is also further transmitted to the other terminal of the capacitor C2 via the conductive third transistor T3, thereby a relatively high crossing voltage (e.g., 16V) is generated between the two terminals of the capacitor C2.

As depicted in FIG. 4A, the second transistor T2 and the third transistor T3 can be thin film transistors; therefore, when the conductive second transistor T2 writes a display data to one terminal of the capacitor C2 from the data line Data, simultaneously the conductive third transistor T3 can also write a common voltage to the other one terminal of the capacitor C2 from the alternating voltage source 42. Furthermore, when multiple pixel circuits 40 together use one alternating voltage source 42 functioning as a common voltage provider, the third transistor T3 can be switched to OFF if the polarity of the common voltage supplied from the alternating voltage source 42 is not suitable for the use of the current pixel, consequently all the pixel circuits can still together use one common voltage provider without having a complicate or modulating design to the common voltage provider.

As described above that the second transistor T2 and the third transistor T3 can be a thin film transistor, thereby the present invention also provides a corresponding manufacture design of the transistor. Please refer to FIG. 4B which is a schematic diagram illustrating a cross-sectional view of a manufacture procedure of the thin film transistor for the implementation of the second transistor T2 and the third transistor T3 in accordance with an embodiment. As depicted in FIG. 4B, a first mental layer (M2) 52 is firstly formed; an isolation layer (PASS) 54 is then formed on the top of the first mental layer (M2) 52; afterwards, a second mental layer (M2) 56 is formed on the top of the isolation layer (PASS) 54; finally an indium tin oxide (ITO) 58 is formed on the top of the second mental layer (M2) 56. As depicted in FIG. 4B, the first mental layer (M2) 52 is configured for the transmission of the display data supplied from the data line Data; and the second mental layer (M2) 56 and the indium tin oxide (ITO) 58 are configured to the transmission of the common voltage Vcom supplied from the alternating voltage source 42. As depicted in FIG. 4B, because a full contact is formed between the second mental layer (M2) 56 and the indium tin oxide (ITO) 58, the resistance existed in the second mental layer (M2) 56 and indium tin oxide (ITO) 58 is almost same as that in the first mental layer (M2) 52, thereby the resistance of the transmitting path of the common voltage decreases greatly. For example, in the embodiment, the sheet resistance of the transmitting path of the common voltage is about 0.2 Ω/m, which is much lower than a normal value about 80 Ω/m. Moreover, as depicted in FIG. 4B, it is noted that the first mental layer (M2) 52 and the second mental layer (M2) 56 adopt a same mask procedure, thereby the first mental layer (M2) 52 and the second mental layer (M2) 56 may have same material or patterns.

FIG. 4C is a schematic diagram illustrating a cross-sectional view of another manufacture procedure of the thin film transistor for the implementation of the second transistor T2 and the third transistor T3 in accordance with another embodiment. The manufacture procedure illustrated in FIG. 4C is similar to that in FIG. 4C except that an ultra high aperture ratio (UHA) layer (or a color-filter manufacture procedure (COA)) 60 is formed between the isolation layer (PASS) 54 and the second mental layer (M2) 56. In other words, the ultra high aperture ratio (UHA) layer (or a color-filter manufacture procedure (COA)) 60 is firstly formed on the top of the isolation layer (PASS) 54, and the second mental layer (M2) 56 is then formed on the top of the ultra high aperture ratio (UHA) layer (or a color-filter manufacture procedure (COA)) 60. The ultra high aperture ratio (UHA) layer (or a color-filter manufacture procedure (COA)) 60 is used to reduce the coupling effect between the first mental layer (M2) 52 and the second mental layer (M2) 56, consequently an interacting effect between the signals respectively transmitted by the first mental layer (M2) 52 and the second mental layer (M2) 56 is reduced.

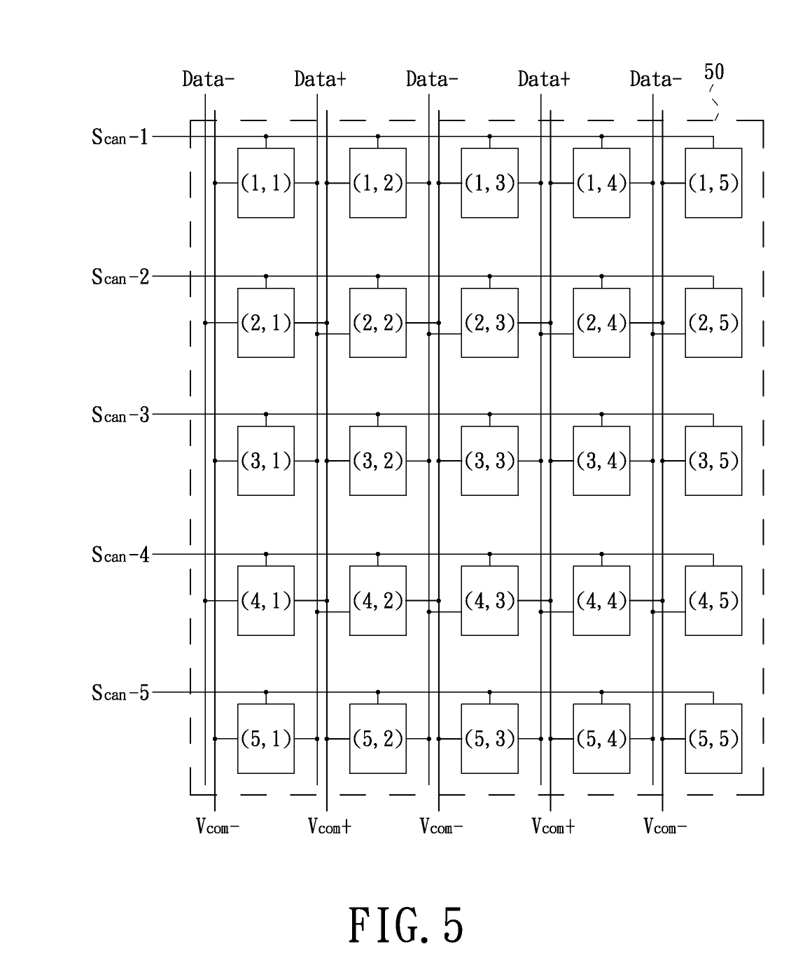

Please refer back to FIG. 3. As depicted in FIG. 3, all the common voltage lines are configured to generally extend in a same direction of the scan lines (extend to a horizontal direction of the surface of the diagram). It is understood that all the common voltage lines can be also configured to generally extend in a same direction of the data lines (extend to a vertical direction of the surface of the diagram). FIG. 5 is a schematic circuit block diagram of a dot-inversion display panel 50 in accordance with another embodiment of the present invention. As depicted in FIG. 5, all the common voltage lines are configured to generally extend in a same direction of the data lines.

To sum up, in the dot-inversion display panel of the present invention, because the display data and the common voltage supplied to a same pixel circuit are polarity-inverse to each other when the pixel circuit displays a same flame, thereby a relatively high crossing voltage is generated in each of the pixel circuits, and therefore some display panels of specific types, such as the blue-polarity display panel requires a higher crossing voltage, can be successfully driven by the relatively high crossing voltage to generate a proper brightness degree.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A driving method of a differential voltage driving device comprising the steps of:
supplying an alternating common voltage in a first polarity to a first terminal of the differential voltage driven device and supplying a first display data in a second polarity to a second terminal of the differential voltage driven device in a first frame;
disconnecting the differential voltage driven device from the alternating common voltage, thereby keeping the first terminal at the first polarity of the alternating common voltage;
converting the alternating common voltage to the second polarity in a second frame which is consecutive to the first frame; and
supplying the alternating common voltage in the second polarity to the first terminal of the differential voltage driven device and supplying a second display data in the first polarity to the second terminal of the differential voltage driven device in the second frame,
wherein the first polarity is inverse to the second polarity, and the differential voltage driven device performs a corresponding operation according to a differential voltage between the first and second terminals.

2. A display panel, comprising:
a plurality of data lines;
a plurality of scan lines;
two groups of common voltage lines for respectively supplying different voltages with polarity-inverse to each other; and
a plurality of pixel circuits, arranged in array, wherein each of the pixel circuits is electrically coupled to one of the data lines and one of the scan lines, and each of the pixel circuits comprises:
a first switch, electrically coupled to the corresponding scan line and the corresponding data line and for determining whether to transmit a voltage on the corresponding data line according to a gate line voltage on the corresponding scan line;
a second switch, electrically coupled to one of the two groups of common voltage lines and the corresponding scan line and for determining whether to transmit a voltage on the coupled common voltage line according to the gate line voltage on the corresponding scan line; and
a capacitor, wherein one terminal of the capacitor is electrically coupled to the first switch for receiving the voltage on the corresponding data line, and the other terminal of the capacitor is electrically coupled to the second switch for receiving the voltage on the coupled common voltage line,
wherein the two voltages respectively received by the two terminals of the capacitor in each of the pixel circuits are polarity-inverse to each other.

3. The display panel according to claim 2, wherein the first and second switches are thin film transistors.

4. The display panel according to claim 2, wherein the two groups of common voltage lines generally extend in a same direction of the data lines.

5. The display panel according to claim 4, wherein any two of the pixel circuits, consecutively electrically coupled to the same data line, are respectively arranged on two sides of the data line, and are electrically coupled to the same group of common voltage lines.

6. The display panel according to claim 2, wherein the two groups of common voltage lines generally extend in a same direction of the scan lines.

7. The display panel according to claim 6, wherein any two of the pixel circuits, consecutively electrically coupled to the same data line, are respectively arranged on two sides of the data line, and are electrically coupled to the same group of common voltage lines.

8. The display panel according to claim 2, wherein the pixel circuits of a same column are alternately electrically couple to the two groups of common voltage lines, the pixel circuits of a same row are alternately electrically couple to the two groups of common voltage lines.

9. The display panel according to claim 3, wherein the thin film transistor comprises:
a first mental layer;
an isolation layer, formed on top of the first mental layer;
a second mental layer, formed on top of the isolation layer; and
an indium tin oxide, form on top of the second mental layer,
wherein a full contact is formed between the second mental layer and the indium tin oxide.

10. The display panel according to claim 3, wherein the thin film transistor comprises:
a first mental layer;
an isolation layer, formed on top of the first mental layer;
a color-filter manufacture procedure, formed on top of the isolation layer;
a second mental layer, formed on top of the color-filter manufacture procedure; and
an indium tin oxide, formed on top of the second mental layer,
wherein a full contact is formed between the second mental layer and the indium tin oxide.

11. A pixel circuit electrically coupled to a data line, a scan line and a common voltage line, and comprising:
a first switch, electrically coupled to the scan line and the data line and for determining whether to transmit a voltage on the data line according to a gate line voltage on the scan line;
a second switch, electrically coupled to the common voltage line and the scan line and for determining whether to transmit a voltage on the common voltage line according to the gate line voltage on the scan line; and
a capacitor, wherein one terminal of the capacitor is electrically coupled to the first switch for receiving the voltage on the data line, and the other terminal of the capacitor is electrically coupled to the second switch for receiving the voltage on the common voltage line,
wherein the two voltages respectively received by the two terminals of the capacitor are polarity-inverse to each other.

12. The pixel circuit according to claim 11, wherein the first and second switches are thin film transistors.

13. The pixel circuit according to claim 12, wherein the thin film transistor comprises:
a first mental layer;
an isolation layer, formed on top of the first mental layer;
a second mental layer, formed on top of the isolation layer; and
an indium tin oxide, form on top of the second mental layer,
wherein a full contact is formed between the second mental layer and the indium tin oxide.

14. The pixel circuit according to claim 12, wherein the thin film transistor comprises:
a first mental layer;
an isolation layer, formed on top of the first mental layer;
a color-filter manufacture procedure, formed on top of the isolation layer;
a second mental layer, formed on top of the color-filter manufacture procedure; and
an indium tin oxide, form on top of the second mental layer,
wherein a full contact is formed between the second mental layer and the indium tin oxide.
